(19) United States
(12) Patent Application Publication
(10) Pub. No.: US 2010/0212129 A1
(43) Pub. Date: Aug. 26, 2010

(54) METHOD FOR MANUFACTURING LIQUID EJECTING HEAD AND METHOD FOR MANUFACTURING ACTUATOR DEVICE

(75) Inventor: Toshiki HARA, Suwa-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/706,344

(22) Filed: Feb. 16, 2010

(30) Foreign Application Priority Data
Feb. 25, 2009 (JP) 2009-041912

(51) Int. Cl. H01L 41/22

(52) U.S. Cl. 29/25.35

(57) ABSTRACT

A method for manufacturing a liquid ejecting head, which has a piezoelectric element including a first electrode, a piezoelectric layer formed on the first electrode, and a second electrode formed on the piezoelectric layer on the opposite side of the first electrode. The liquid ejecting head ejects liquid droplets from a nozzle opening by generating pressure in a pressure-generating chamber using the piezoelectric element. The method includes forming the first electrode, forming a piezoelectric precursor film on the first electrode, first heat treatment of forming a piezoelectric film by crystallizing the piezoelectric precursor film by heat treatment, forming the second electrode, and second heat treatment of heating the piezoelectric layer composed of the piezoelectric film at a temperature of 150° C. or more while applying a voltage between the first electrode and the second electrode.

### CROSS-REFERENCE TO RELATED APPLICATIONS

This application claims the benefit of priority to Japanese Patent Application No. 2009-041912 filed Feb. 25, 2009, the contents of which are hereby incorporated by reference in their entirety.

### BACKGROUND

1. Technical Field

The present invention relates to a method for manufacturing a liquid ejecting head and a method for manufacturing an actuator device, which include a piezoelectric element having a first electrode, a piezoelectric layer, and a second electrode.

2. Related Art

A piezoelectric element for use in liquid ejecting heads or the like has a structure in which a piezoelectric layer made of a piezoelectric material having an electromechanical transduction function is interposed between two electrodes. A typical example of such liquid ejecting heads is an ink jet recording head structured in a manner such that part of a pressure-generating chamber communicating with a nozzle opening from which ink droplets are ejected is constituted by a diaphragm and a piezoelectric element deforms the diaphragm so as to apply a pressure to ink in the pressure-generating chamber, so that ink droplets are ejected from the nozzle opening. An example of such a piezoelectric element mounted on ink jet recording heads is a piezoelectric element produced by forming a uniform piezoelectric material layer by a film-forming technique over the entire surface of a diaphragm and separating the piezoelectric material layer by lithography in such a manner that each piezoelectric element has a shape corresponding to each pressure-generating chamber.

Japanese Unexamined Patent Application Publication No. 2003-163387 discloses a piezoelectric element. However, the problem of this piezoelectric element with such a configuration is that the displacement characteristics of a piezoelectric material layer have a relatively large variation. If the piezoelectric layer does not have good displacement characteristics, the movement of the piezoelectric element is inefficient, and thus it is necessary to change the liquid ejecting conditions of an ink jet recording head.

In addition, this problem is not limited to the liquid ejecting head, typically an ink jet recording head, but is also present in actuator devices mounted on other devices.

### SUMMARY

An advantage of some aspects of the invention is to provide a method for manufacturing a liquid ejecting head and a method for manufacturing an actuator device, which have excellent displacement characteristics.

In an aspect of the present invention, there is provided a method for manufacturing a liquid ejecting head, which has a piezoelectric element including a first electrode, a piezoelectric layer formed on the first electrode, and a second electrode formed on the piezoelectric layer on the opposite side of the first electrode. The liquid ejecting head ejects liquid droplets from a nozzle opening by generating pressure in a pressure-generating chamber using the piezoelectric element. The method may include a process of forming the first electrode, a process of forming a piezoelectric precursor film on the first electrode, a first heat treatment of forming a piezoelectric film by crystallizing the piezoelectric precursor film by heat treatment, a process of forming the second electrode, and a second heat treatment of heating the piezoelectric layer composed of the piezoelectric film at a temperature of 150° C. or more while applying a voltage between the first electrode and the second electrode.

According to this aspect, even if complex deficiency occurs in the crystal of the piezoelectric layer, the complex deficiency can be removed by the second heat treatment. In addition, the complex deficiency of the piezoelectric layer is prevented from occurring again after the second heat treatment. Thereby, the piezoelectric element having excellent displacement characteristics can be produced by reducing the complex deficiency of the piezoelectric layer. As a result, the liquid ejecting head having excellent liquid ejecting characteristics can be manufactured.

The second head treatment can preferably be performed after the second electrode is formed as a film and the piezoelectric layer and the second electrode are patterned. Due to this process, complex deficiency can be removed even if it occurs in the patterning.

The second heat treatment can preferably be performed in an oxygen atmosphere. Due to this process, even if oxygen deficiency (oxygen vacancy) occurs in the crystal of the piezoelectric layer, complex deficiency can be removed since oxygen can be introduced to the oxygen deficiency. In addition, this can further prevent the complex deficiency from being created again after the second heat treatment. Thereby, excellent displacement characteristics can be obtained by reducing the complex deficiency of the piezoelectric layer.

The second heat treatment can preferably be performed by applying a voltage of 1 to 30 V between the first electrode and the second electrode. Due to this process, complex deficiency can be properly removed from the crystal of the piezoelectric layer in the second heat treatment.

If the thickness of the piezoelectric layer is 5 μm or less, the piezoelectric layer is vulnerable to complex deficiency. However, excellent displacement characteristics can be obtained by reducing the complex deficiency of the piezoelectric layer.

When one or more of the first electrode and the second electrode contains at least one selected from the group consisting of Ni, Cu, Nb, Ru, Rh, Pd, Ag, Sn, Os, Ir, Pt, Au, and Bi, excellent displacement characteristics can be obtained by reducing the complex deficiency of the piezoelectric layer.

Both the first heat treatment and the second heat treatment can preferably be performed at the same time after the second electrode is formed on the piezoelectric precursor film. Due to this process, excellent displacement characteristics can be obtained by reducing the complex deficiency of the piezoelectric layer using the simplified process.

The method may sequentially perform a process of forming a plurality of piezoelectric films by repeating the process of forming a piezoelectric precursor film and the first heat treatment, a process of forming a piezoelectric precursor film in the uppermost layer of the piezoelectric films, and a process of forming the second electrode as a film on the piezoelectric precursor film, and simultaneously performing the first heat treatment and the second heat treatment, in which the first heat treatment forms an uppermost piezoelectric film by crystallizing the uppermost piezoelectric precursor film through heat treatment by heating at a temperature of 150° C. or more while applying a voltage between the first electrode and the second electrode. This makes it possible to remove complex deficiency from the piezoelectric films other than the uppermost piezoelectric film while forming the uppermost piezoelectric film.

In another aspect of the present invention, there is provided a method for manufacturing an actuator, which has a piezoelectric element including a first electrode, a piezoelectric layer formed on the first electrode, and a second electrode formed on the piezoelectric layer. The method may include a process of forming the first electrode, a process of forming a piezoelectric precursor film above the first electrode, a first heat treatment of forming a piezoelectric film by crystallizing the piezoelectric precursor film by heat treatment, a process of forming the second electrode, and a second heat treatment of heating the piezoelectric layer composed of the piezoelectric film at a temperature of 150° C. or more while applying a voltage between the first electrode and the second electrode.

According to this aspect, even if complex deficiency occurs in the crystal of the piezoelectric layer, the complex deficiency can be removed by the second heat treatment. In addition, the complex deficiency is prevented from occurring again after the second heat treatment. Thereby, an actuator device having excellent displacement characteristics can be produced by reducing the complex deficiency of the piezoelectric layer.

### BRIEF DESCRIPTION OF THE DRAWINGS

The invention will be described with reference to the accompanying drawings, wherein like numbers reference like elements.

FIG. 1 is an exploded perspective view showing a schematic configuration of a recording head in accordance with a first exemplary embodiment of the invention.

FIG. 2A is a plan view showing the recording head in accordance with the first exemplary embodiment of the invention, and FIG. 2B is a cross-sectional view showing the recording head in accordance with the first exemplary embodiment of the invention.

FIGS. 3A to 3D are cross-sectional views showing a method for manufacturing a recording head in accordance with the first exemplary embodiment of the invention.

FIGS. 4A to 4C are cross-sectional views showing a method for manufacturing a recording head in accordance with the first exemplary embodiment of the invention.

FIGS. 5A and 5B are cross-sectional views showing a method for manufacturing a recording head in accordance with the first exemplary embodiment of the invention.

FIGS. 6A to 6C are schematic diagrams showing a mechanism by which a complex deficiency is created.

FIGS. 7A and 7B are schematic diagrams showing a mechanism by which a complex deficiency is removed.

FIGS. 8A and 8B are schematic diagrams showing a mechanism by which a complex deficiency is removed.

FIGS. 9A to 9C are cross-sectional views showing a method for manufacturing a recording head in accordance with the first exemplary embodiment of the invention.

FIGS. 10A and 10B are cross-sectional views showing a method for manufacturing a recording head in accordance with the first exemplary embodiment of the invention.

FIGS. 11A to 11D are cross-sectional views showing a method for manufacturing a recording head in accordance with a second exemplary embodiment of the invention.

FIG. 12 is a perspective view illustrating an example of a schematic configuration of a recording device.

### DESCRIPTION OF EXEMPLARY EMBODIMENTS

The present invention will now be described more fully hereinafter with reference to exemplary embodiments thereof.

### First Exemplary Embodiment

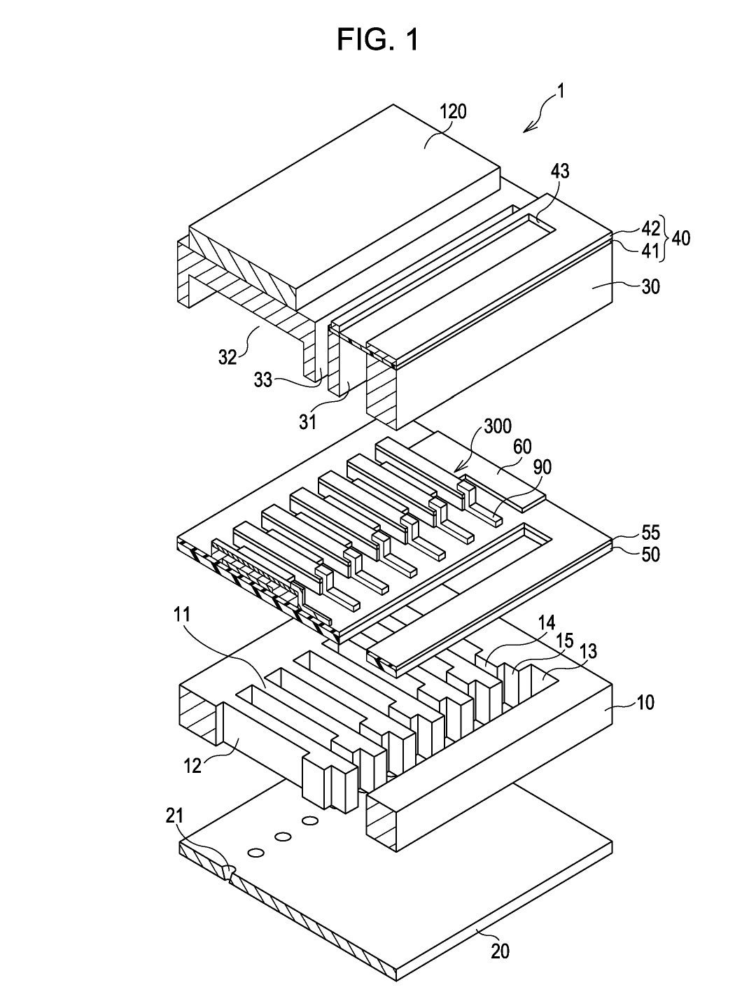

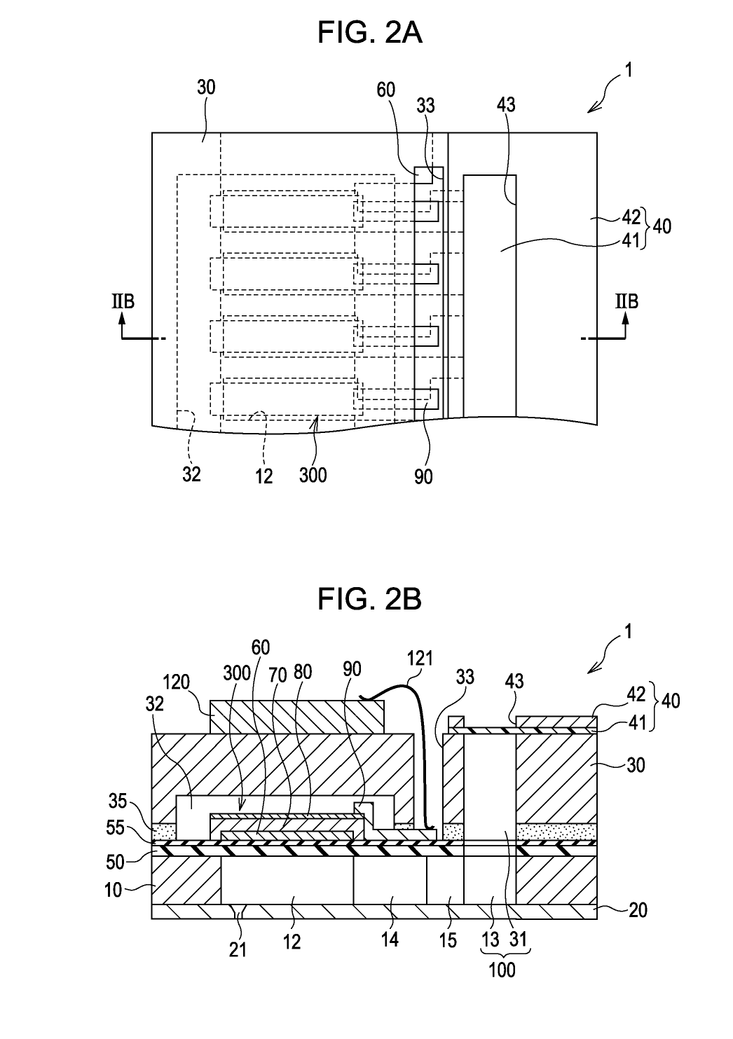

FIG. 1 is an exploded perspective view showing a schematic configuration of an ink jet recording head as an example of a liquid ejecting head in accordance with a first exemplary embodiment of the invention, FIG. 2A is a plan view of a passage-forming substrate, and FIG. 2B is a cross-sectional view taken along line IIB-IIB of FIG. 2A.

As shown in the figures, a passage-forming substrate 10 is made of a Si single-crystal substrate in this exemplary embodiment. An elastic film 50 made of an oxide layer is formed on one surface of the passage-forming substrate 10.

In the passage-forming substrate 10, a plurality of pressure-generating chambers 12 are arranged in the width direction. In addition, a communicating portion 13 is formed in the passage-forming substrate 10, in a portion longitudinally outward of the pressure-generating chambers 12 of the passage-forming substrate 10. The communicating portion 13 is connected to the respective pressure-generating chamber 12 by an ink supply passage 14 and a communicating passage 15, which are provided in each pressure-generating chamber 12. The communicating portion 13 constitutes a part of a reservoir that forms a common ink chamber of the respective pressure-generating chambers 12 by communicating with a reservoir portion 31 of a protective substrate, which will be described later. The ink supply passage 14 has a width smaller than the pressure-generating chamber 12, and serves to maintain flow resistance against ink, flowing from the communicating portion 13 to the pressure-generating chamber 12. In addition, although the ink supply passage 14 is formed by narrowing the width of the passage from one side in this exemplary embodiment, the ink supply passage can be formed by narrowing the width of the passage from both sides. Furthermore, the ink supply passage can be formed by narrowing the thickness rather than narrowing the width of the passage.

In addition, a nozzle plate 20, in which nozzle openings 21 are perforated, is fixed to the open surface of the passage-forming substrate 10 by adhesive or a thermal deposition film in such a manner that each of the nozzle openings 21 communicates with each of the pressure-generating chambers 12, in a portion adjacent to one end opposite the ink supply passage 14. The nozzle plate 20 is made of, for example, glass ceramics, a Si single-crystal substrate, or stainless steel.

In addition, the elastic film 50 as described above is formed opposite the open surface of the passage-forming substrate 10, and an insulating film 55 is formed over the elastic film 50. A first electrode 60, a piezoelectric layer 70, and a second electrode 80 are stacked over the insulating film 55 by the following process, thereby constituting a piezoelectric element 300. Here, the piezoelectric element 300 indicates the parts including the first electrode 60, the piezoelectric layer 70, and the second electrode 80. In general, one of electrodes of the piezoelectric element 300 is set as a common electrode, and the other electrode of the piezoelectric element 300 and the piezoelectric layer 70 are patterned for the respective pressure-generating chambers 12. Both the patterned electrode and the patterned piezoelectric layer 70 constitute a piezoelectric active portion, in which piezoelectric bending occurs in response to the application of voltage to both electrodes. In this exemplary embodiment, the first electrode 60 is used as the common electrode of the piezoelectric element 300, and the second electrode 80 is used as an individual electrode of the piezoelectric element 300. The first and second electrodes may be used in the opposite manner in consideration of a drive circuit or lines. In addition, the piezoelectric element 300 and a diaphragm that generates displacement in response to the drive of the piezoelectric element 300 are collectively referred to as an actuator device. In addition, in the foregoing example, the elastic film 50, the insulating film 55, and the first electrode 60 function as the diaphragm. However, this is not intended to be limiting. For example, only the first electrode 60 can be designed to function as the diagram without the elastic film 50 or the insulating film 55. Of course, the piezoelectric element 300 itself can be designed to have the function of the diaphragm.

In this exemplary embodiment, the piezoelectric element 300 includes the first electrode 60 made of Pt, the piezoelectric layer 70 made of PZT (Lead Zirconate Titanate), and the second electrode 80 made of Ir. Although the first electrode 60 is made of Pt and the second electrode 80 is made of Ir in this exemplary embodiment, this is not intended to be limiting. For example, the first and second electrodes 60 and 80 can be made of a variety of metal materials such as Ni, Cu, Nb, Ru, Rh, Pd, Ag, Sn, Os, Ir, Pt, Au, Bi, a stack thereof, or an alloy thereof. Of course, the first and second electrodes 60 and 80 can be made of a conductive material in addition to the former.

Specifically, the piezoelectric layer 70 is formed by a manufacturing method, which will be described later. The material of the piezoelectric layer 70 is not specifically limited as long as a sufficient amount of displacement can be obtained during practical use. Preferably, the material of the piezoelectric layer 70 has a Perovskite structure composed of a piezoelectric material of an oxide, which is expressed by a general formula ABO₃. The piezoelectric layer 70 can be preferably made of, for example, a strong dielectric material such as PZT, or by adding metal oxide such as niobium oxide, nickel oxide, or magnesium oxide to the strong dielectric material. In detail, PbTiO₃, Pb(Zr, Ti)O₃, PbZrO₃, (Pb, La)TiO₃, (Pb, La) (Zr, Ti)O₃, or Pb(Zr, Ti) (Mg, Nb)O₃, and the like can be properly used. The thickness of the piezoelectric layer 70 is limited such that cracks do not occur in the fabrication process, and at the same time, is thick enough such that sufficient displacement characteristics can be present. For example, the thickness of the piezoelectric layer 70 is preferably from 1 to 5 μm. In this embodiment, the thickness of the piezoelectric layer 70 is about 1 μm.

In addition, the respective second electrodes 80, which are individual electrodes of the piezoelectric element 300, are connected with lead electrodes 90, respectively. Each of the lead electrodes 90 is drawn from a portion adjacent to the end of the ink supply passage 14 side and is extended to the insulating film 55. The lead electrodes 90 are made of, for example, Au.

A protective substrate 30 having the reservoir portion 31, which constitutes at least a portion of the reservoir 100, is bonded onto the passage-forming substrate 10, in which the piezoelectric element 300 is formed, via adhesive 35. In this exemplary embodiment, the reservoir portion 31 is formed across the width direction of the pressure-generating chambers 12, extending through the protective substrate 30 in the thickness direction. As described above, the reservoir portion 31 communicates with the communicating portion 13 of the passage-forming substrate 10, thereby constituting the reservoir 100 that is the common ink chamber of the respective pressure-generating chambers 12. In addition, only the reservoir portion 31 can be provided as the reservoir by dividing the communicating portion 13 of the passage-forming substrate 10 into multiple sections corresponding to the pressure-generating chambers 12, respectively. In addition, for example, only the pressure-generating chambers 12 can be provided in the passage-forming substrate 10 such that the ink supply passages 14 communicating between the reservoir and the respective pressure-generating chamber 12 are provided in a member (e.g., the elastic film 50 or the insulating film 55) interposed between the passage-forming substrate 10 and the protective substrate 30.

In addition, a piezoelectric element holder 32, which has a space that does not interfere with the movement of the piezoelectric element 300, is provided in a portion of the protective substrate 30 opposite to the piezoelectric element 300. The space of piezoelectric element holder 32 is required not to interfere with the movement of the piezoelectric element 300. The space can be sealed or unsealed.

The protective substrate 30 can be made of a material such as glass or ceramics, the thermal expansion rate of which is substantially the same as that of the passage-forming substrate 10. In this exemplary embodiment, the protective substrate 30 is formed using a Si single-crystal substrate, which is the same material as the passage-forming substrate 10.

In addition, the protective substrate 30 has through-holes 33 that extend through the protective substrate 30 in the thickness direction. In addition, the vicinity of the end portions of the lead electrodes 90, withdrawn from the respective piezoelectric elements 300, is exposed inside the through holes 33.

In addition, a drive circuit 120 for driving the piezoelectric elements 300, which are arranged side by side, is fixed on the protective substrate 30. The drive circuit 120 can be implemented by a circuit board, a semiconductor IC (Integrated Circuit), or the like. The drive circuit 120 and the lead electrodes 90 are electrically connected to each other via interconnect lines 121 made of conductive wires such as bonding wires.

In addition, a compliance substrate 40, which includes a sealing film 41 and a fixing plate 42, is bonded onto the protective substrate 30. The sealing film 41 is made of a flexible material having low rigidity, and one side of the reservoir portion 31 is sealed by the sealing film 41. In addition, the fixing plate 42 is made of a relatively rigid material. The portion of the fixing plate 42 opposite the reservoir 100 forms an opening 43, which is completely removed in the thickness direction, such that one side of the reservoir 100 is sealed by only the flexible sealing film 41.

The ink jet recording head of this exemplary embodiment as described above ejects ink droplets from the nozzle opening 21 by receiving ink from an ink inlet connected to an external ink supply unit (not shown), filling the inside with ink until ink reaches the nozzle opening 21 from the reservoir 100, applying a voltage between the respective first and second electrodes 60 and 80, corresponding to the respective pressure-generating chamber 12, in response to a recording signal from the drive circuit 120, and then deforming the elastic film 50, the insulating film 55, the first electrode 60, and the piezoelectric layer 70 to bend, thereby raising the pressure inside the respective pressure-generating chamber 12.

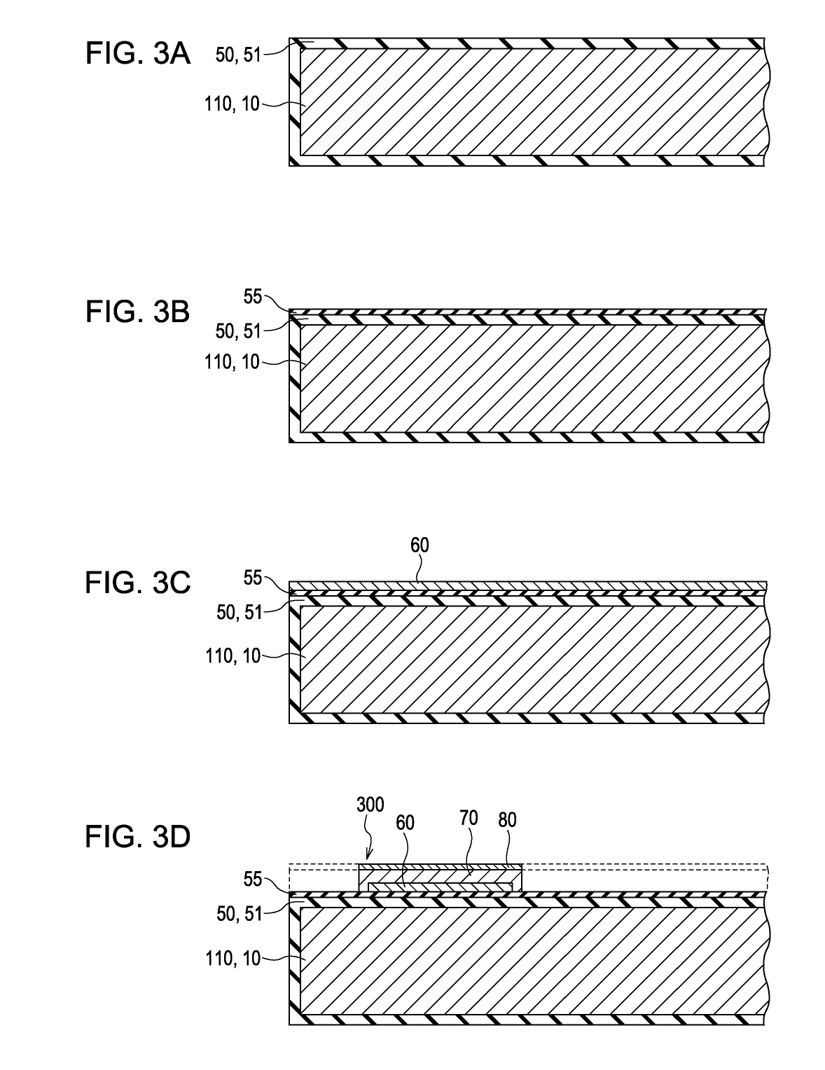

A method for manufacturing an ink jet recording head will be described hereinafter with reference to FIGS. 3 to 6. FIGS. 3 to 6 are cross-sectional views showing the method for manufacturing an ink jet recording head.

First, as shown in FIG. 3A, a silicon dioxide film 51 made of SiO₂, which constitutes an elastic film 50, is formed over the surface of a passage-forming substrate wafer 110, in which a plurality of passage-forming substrates 10 are integrally formed. Then, as shown in FIG. 3B, an insulating film 55 made of, for example, zirconium oxide is formed over the elastic film 50 (silicon dioxide film 51).

Then, as shown in FIG. 3C, a first electrode 60 made of Pt is formed over the insulating film 55. A method for forming the first electrode 60 is not specifically limited. For example, the first electrode 60 can be formed by sputtering, CVD (Chemical Vapor Deposition), PVD (Physical Vapor Deposition), or the like. Although the material of the first electrode 60 is not specifically limited as described above, in the case where the piezoelectric layer 70 is made of PZT as in this exemplary embodiment, the material of the first electrode 60 can preferably be Pt, Ir, or the like. This is because it is preferable that the materials have little change in conductivity due to diffusion of lead oxide.

Next, a piezoelectric layer 70 made of PZT or the like is formed over the entire surface of the passage-forming substrate wafer 110. In addition, in this exemplary embodiment, the piezoelectric layer 70 made of metal oxide is formed by the so-called sol-gel method, which includes forming gel by applying and drying sol, in which metal organic material is dissolved and dispersed into solvent, and then performing calcination at high temperature. In addition, the method for forming the piezoelectric layer 70 is not specifically limited. For example, the piezoelectric layer 70 can be formed by methods such as MOD (Metal-Organic Decomposition), sputtering and PVD (Physical Vapor Deposition) such as laser ablation.

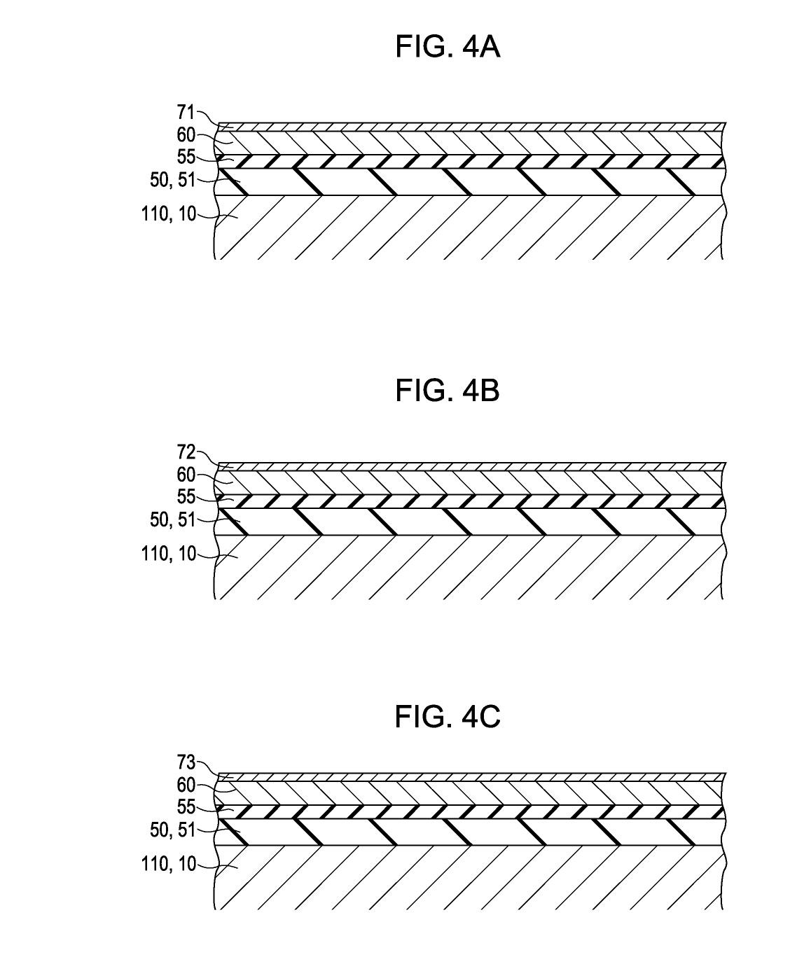

Detailed sequences of forming the piezoelectric layer 70 will be described. First, as shown in FIG. 4A, a constituent humor 71 for piezoelectric film is applied over the first electrode 60 (application process). The constituent humor 71 applied in the application process is sol that contains organic metal compound for forming a PZT precursor film.

Then, an amorphous piezoelectric precursor film 72, as shown in FIG. 4B, is formed by heat treating the constituent humor 71 for piezoelectric film. Specifically, the piezoelectric precursor film 72 is formed by heating the constituent humor 71 for piezoelectric film at a predetermined temperature, followed by drying for a predetermined time (drying process). For example, in the drying process of this exemplary embodiment, the constituent humor 71 applied over the passage-forming substrate wafer 110 can be dried by maintaining a temperature from 150 to 170° C. for 3 to 30 minutes.

Afterwards, the piezoelectric precursor film 72 dried by the drying process is degreased by heating it at a predetermined temperature, which is maintained a predetermined time (degreasing process). In this exemplary embodiment, the dried piezoelectric precursor film 72 was degreased by heating it at 300 to 400° C., which was maintained for 3 to 30 minutes. Herein, the term “degreasing” indicates removing organic components from the piezoelectric precursor film 72 with the form of NO₂, CO₂, H₂O, or the like.

Next, as shown in FIG. 4C, a piezoelectric film 73 is formed by crystallizing the piezoelectric precursor film 72 by heating it at a predetermined temperature, which is maintained for a predetermined time (calcining process). In this calcining process, the piezoelectric precursor film 72 is preferably heated at 680 to 900° C. In this exemplary embodiment, the piezoelectric film 73 is formed by calcining the piezoelectric precursor film 72 by heating it at 680° C. for 5 to 30 minutes. The calcining process corresponds to “first heat treatment” according to the first aspect of the invention.

In addition, a heating unit in use for the drying, degreasing, and calcining processes as described above can be implemented by a hot plate or an RTP (Rapid Thermal Processing) device that performs heating by irradiation of an infrared lamp.

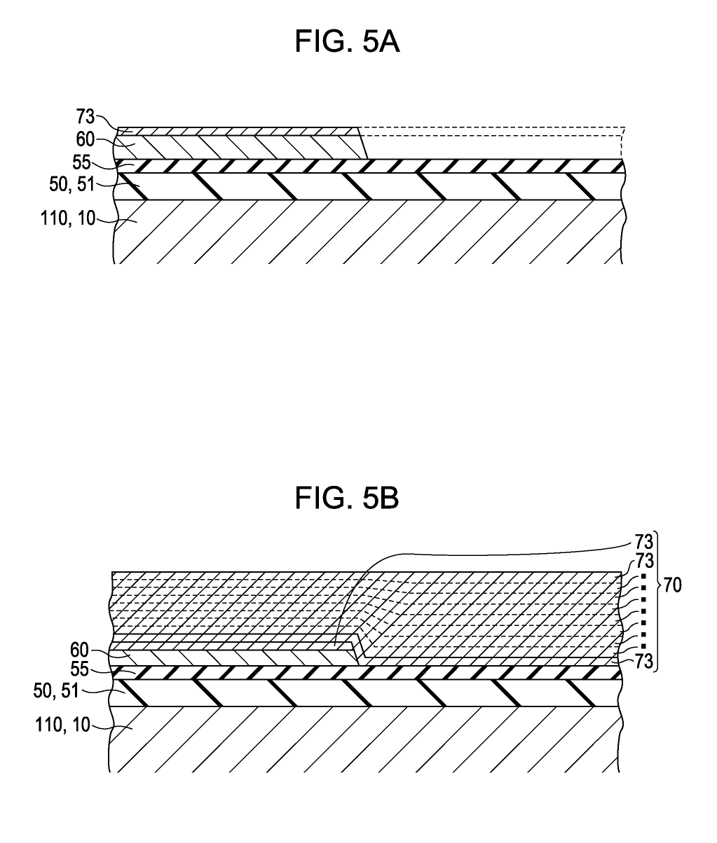

Next, as shown in FIG. 5A, in the step where the piezoelectric film of the first layer 73 is formed over the first electrode 60, the first electrode 60 and the piezoelectric film of the first layer 73 are simultaneously patterned so that their sides are inclined. This can reduce or alleviate an adverse effect on the crystallinity of the piezoelectric film 73 of the second layer, due to a difference in bases, in the surroundings of a boundary between an area where the first electrode 60 and the piezoelectric film 73 of the first layer are formed and the other area when the piezoelectric film 73 of the second layer is formed. Due to this, in the surroundings of a boundary between the first electrode 60 and other area, the crystalline growth the piezoelectric film 73 of the second layer finely proceeded, thereby forming the piezoelectric layer 70 having excellent crystallinity. In addition, the side surfaces of the first electrode 60 and the piezoelectric film 73 of the first layer can be sloped so that the other piezoelectric films 73 of the second layer and the following layers can more efficiently surround and stick to the underlying structure. Thereby, the piezoelectric layer 70 having excellent bonding ability and reliability can be formed. In addition, the patterning of the first electrode 60 and the piezoelectric film 73 of the first layer can be performed by, for example, dry etching such as ion milling.

Afterwards, as shown in FIG. 5B, a piezoelectric layer 70, composed of multiple layers of piezoelectric film 73, is formed at a thickness 1 μm by sequentially and repeatedly performing the applying, drying, degreasing, and calcining processes, as described above, over the passage-forming substrate wafer 110 including the first layer of piezoelectric film 73. In addition, although the piezoelectric layer 70 has been described as being composed of multiple layers of piezoelectric films 73 in this exemplary embodiment, the piezoelectric layer 70 may be made of a single layer of piezoelectric film 73.

Next, a second electrode 80 made of Ir is formed as a film over the piezoelectric layer 70 composed of the multiple layers of piezoelectric films 73. Then, as shown in FIG. 3D, the piezoelectric layer 70 and the second electrode 80 are patterned in the portions opposite respective pressure-generating chambers 12, thereby forming a piezoelectric element 300. A method for patterning the piezoelectric layer 70 and the second electrode 80 can be, for example, dry etching such as reactive ion etching or ion milling.

Afterwards, the piezoelectric layer 70 is heated at a temperature of 150° C. or more while applying a voltage between the first electrode 60 and the second electrode 80 (second heat treatment). Due to the second heat treatment, even if a complex deficiency occurs in a crystal of the piezoelectric layer 70, the complex deficiency can be removed. This, as a result, can significantly reduce the fraction defective of the ink jet recording head. The present invention is based on the aspect that the complex deficiency in the piezoelectric layer is one of the reasons that good displacement characteristics are not obtained, and is intended to efficiently remove the complex deficiency from the piezoelectric layer by heating the piezoelectric layer 70 at a temperature of 150° C. or more while applying a voltage between the first electrode 60 and the second electrode 80; i.e., an electric field generated in the piezoelectric layer 70 is maintained.

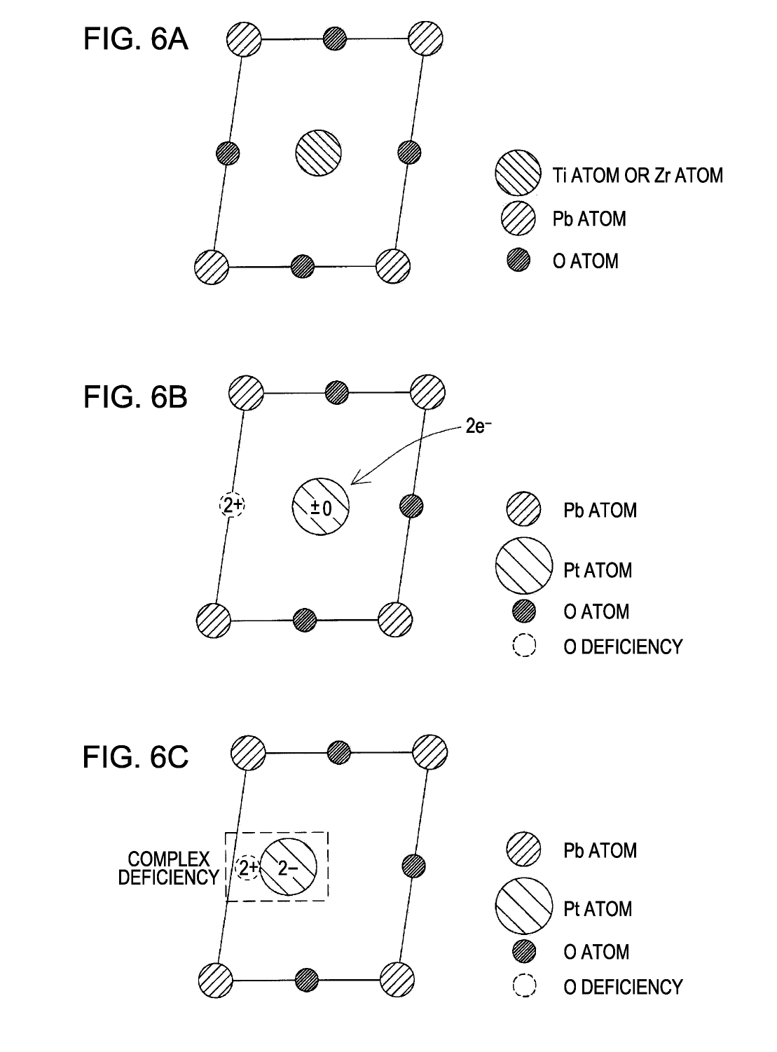

Here, the mechanism forming the complex deficiency in the piezoelectric layer 70 made of PZT is estimated as follows: FIG. 6A shows a crystal structure of PZT before a deficiency occurs in the crystal. Due to deterioration of the crystal of PZT, an oxygen deficiency (V₀²⁺) having a +2 charge occurs in the crystal as shown in FIG. 6B. In addition, the position of a Ti atom of PZT is substituted by a Pb atom or an atom, which is used for the electrode material. Here, the state where Ti atom is substituted by a Pt atom, which is used for the material of the first electrode 60 (Pt_{Ti}⁰) will be described. Even if this Pt_{Ti}⁰ is neutral, it can be negatively charged by trapping an electron.

As shown in FIG. 6C, it is estimated that, when Pt_{Ti}⁰ is negatively charged by trapping an electron and becomes Pt_{Ti}⁻², V₀²⁺ and Pt_{Ti}⁻² are electrically bonded, thereby forming a complex deficiency V₀Pt_{Ti}. The process of forming a complex deficiency is expressed in Formula (1) below.

2e⁻+Pt_{Ti}⁰+V₀²⁺→Pt_{Ti}⁻²+V₀²⁺→V₀Pt_{Ti} Formula (1)

The complex deficiency cannot be simply broken once formed since it has a stable energy state (equal to or more than 1 eV). That is, when the complex deficiency as shown in FIG. 6C occurs, it is difficult to restore the crystal structure as shown in FIG. 6A. In addition, if the complex deficiency is created in the piezoelectric layer 70, intended displacement characteristics cannot be obtained.

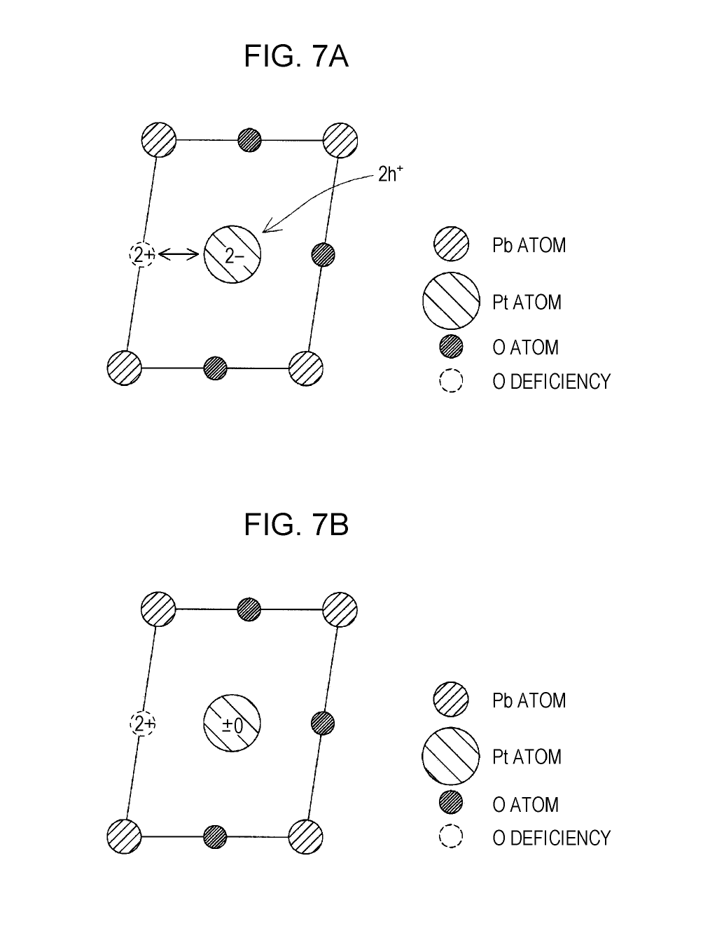

The second heat treatment can remove a complex deficiency of the piezoelectric layer made of PZT if such occurs as above. Specifically, the complex deficiency is dissociated, as shown in FIG. 7A, by heating it at a temperature of 150° C. or more while applying a voltage between the first electrode 60 and the second electrode 80. In addition, a hole is injected due to the voltage applied. In other words, due to thermal energy and electrical repulsion, the complex deficiency is dissociated and negatively-charged Pt_{Ti}⁻² is neutralized)(Pt_{Ti}⁰). As a result, as shown in FIG. 7B, the complex deficiency can be removed. The process of removing the complex deficiency is expressed in Formula (2) below.

2h⁺+V₀Pt_{Ti}→[V₀Pt_{Ti}]²⁺→Pt_{Ti}⁰+V₀²⁺ Formula (2)

As such, since the complex deficiency is dissociated and negatively-charged Pt_{Ti}⁻² is restored to neutral by injecting holes into the crystal, the complex deficiency is not easily created again in the piezoelectric layer 70. That is, this can prevent the complex deficiency from being created again in the piezoelectric layer 70.

In the second heat treatment, the voltage is preferably higher than a Schottky barrier and lower than a voltage which is practically used. For example, the voltage is preferably 1 to 30 V. In addition, the heating temperature in the second heat treatment is not specifically limited as long as it is 150° C. or more and does not deteriorate the performance of the liquid ejecting head. However, when the second heat treatment is performed right after the second electrode 80 is formed, the heating temperature can be, for example, 200 to 400° C. In this exemplary embodiment, heating was performed at 300° C. for 3 minutes with an application voltage of 20 V.

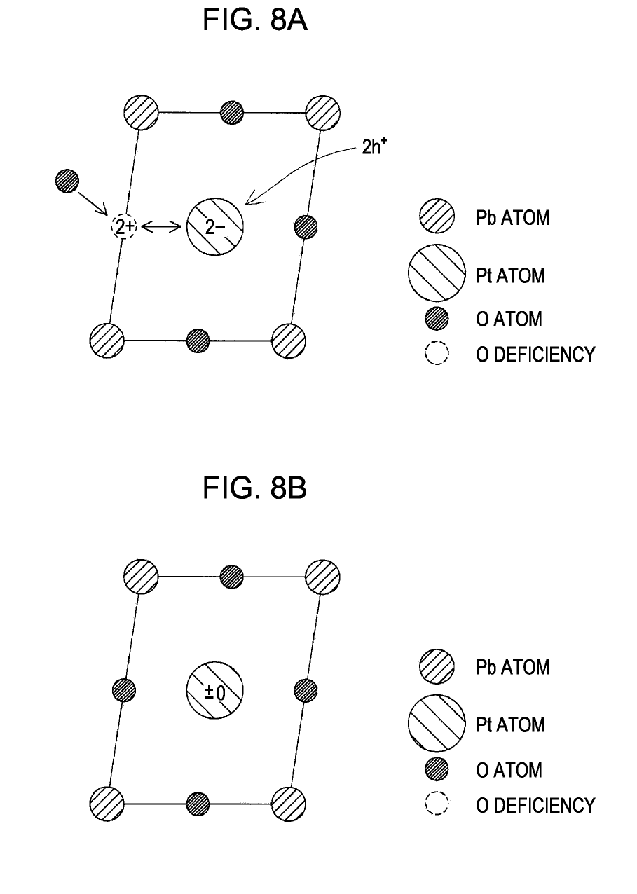

In this exemplary embodiment, the second heat treatment was performed in an oxygen atmosphere. In addition, the oxygen atmosphere refers to an atmosphere where the volume ratio of oxygen is 50 to 100%. In this exemplary embodiment, the second heat treatment was performed in an atmosphere where the volume ratio of oxygen was 100%. Since the second heat treatment is performed in the oxygen atmosphere, an oxygen atom can be introduced into an oxygen deficiency, as shown in FIG. 8A, when negatively-charged Pt_{Ti}⁻² is neutralized into Pt_{Ti}⁰, simultaneously with the dissociation of the complex deficiency. As a result, as shown in FIG. 8B, a crystal structure similar to the original crystal structure (see FIG. 6A) is obtained. This, as a result, can further prevent the complex deficiency from being created again. In addition, since an oxygen atom can be introduced to the oxygen deficiency of the crystal, as shown in FIG. 6B, before the complex deficiency is created, it is possible to prevent the complex deficiency from occurring.

Although the complex deficiency tends to frequently occur in the patterning of the piezoelectric layer 70 and the second electrode 80, this exemplary embodiment makes it possible to remove the complex deficiency, which occurs in the piezoelectric layer 70 in the patterning, by performing the second heat treatment after the patterning of the piezoelectric layer 70 and the second electrode 80. Since the complex deficiency of the piezoelectric layer 70 is suppressed, it is possible to suppress the deterioration in displacement characteristics, which causes due to the complex deficiency, when the piezoelectric element 300 is driven.

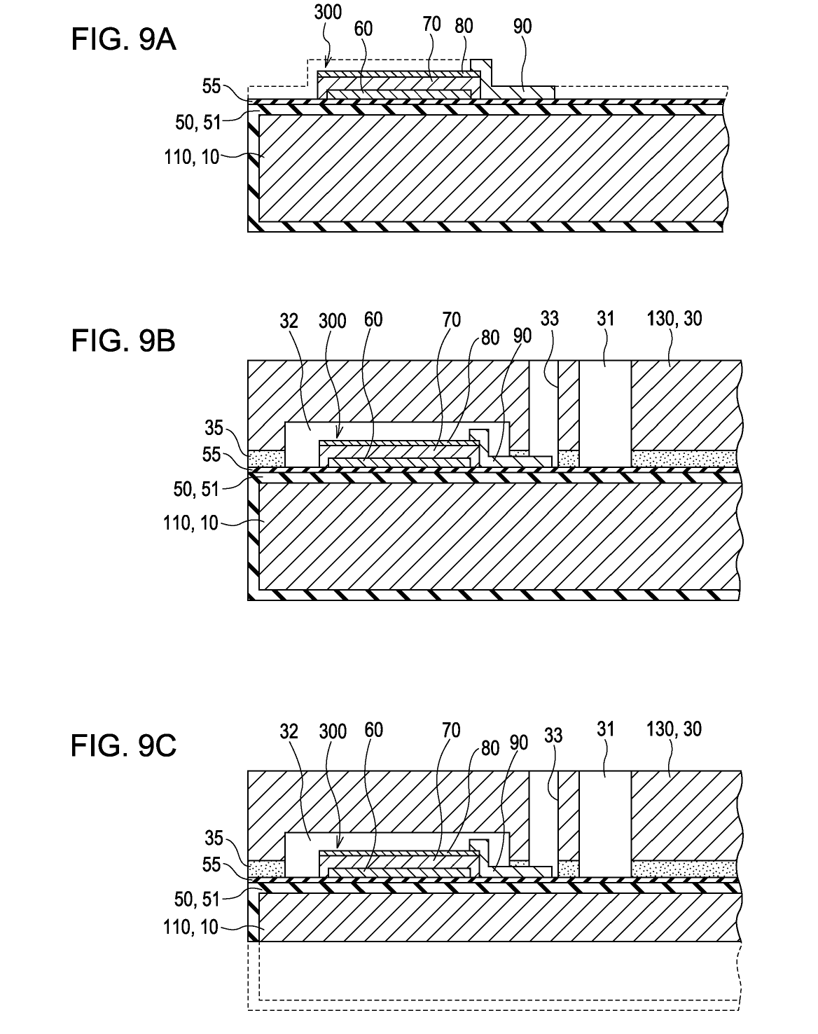

Next, lead electrodes 90 are formed. Specifically, as shown in FIG. 9A, a lead electrode 90 made of, for example, Au or the like is formed over the entire surface of the passage-forming substrate wafer 110, and is then patterned for every piezoelectric element 300 through a mask pattern (not shown) made of, for example, a resist or the like.

Afterwards, as shown in FIG. 9B, a protective substrate wafer 130, which is made of a silicon wafer and will form a plurality of protective substrates 30, is bonded to the passage-forming substrate wafer 110, adjacent to the piezoelectric element 300, via adhesive 35. In addition, a reservoir portion 31, a piezoelectric element holder 32, and the like are previously formed in the protective substrate 30. The protective substrate 30 is made of, for example, a Si single-crystal substrate having a thickness of about 400 μm. The rigidity of the passage-forming substrate 10 can be significantly improved due to the protective substrate 30 bonded to the passage-forming substrate 10. As shown in FIG. 9C, the passage-forming substrate wafer 110 has a predetermined thickness.

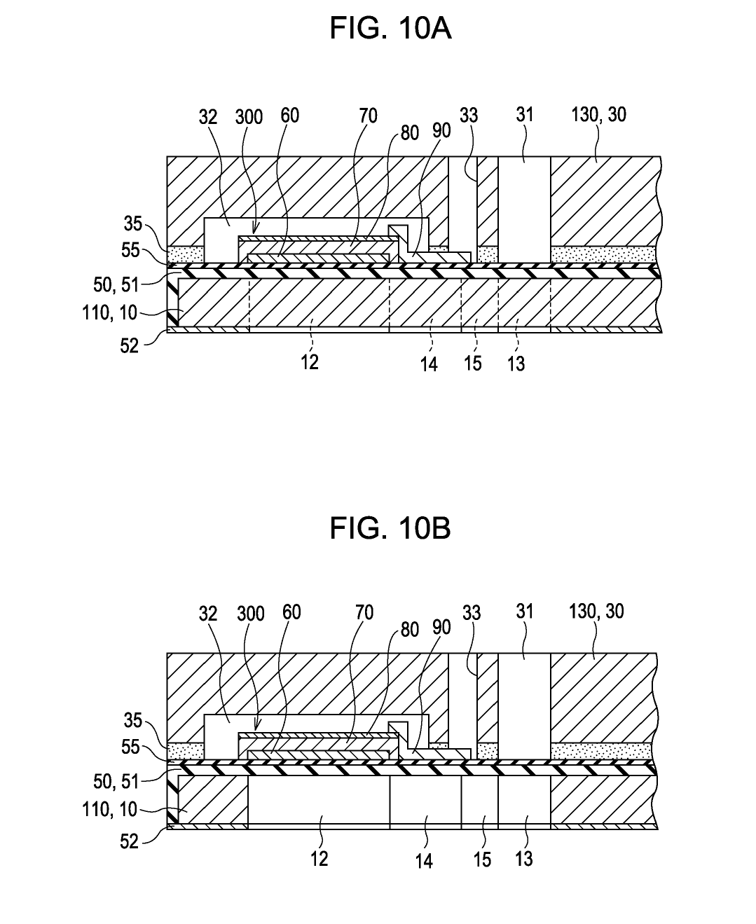

Next, as shown in FIG. 10A, a mask film 52 is newly formed over the passage-forming substrate wafer 110 which is then patterned into a predetermined shape. Then, as shown in FIG. 10B, pressure-generating chambers 12, a communicating portion 13, an ink supply passage 14, a communicating passage 15 and the like, corresponding to the piezoelectric element 300, are formed by performing anisotropic etching (wet etching) on the passage-forming substrate wafer 110 through the mask film 52 using an alkali solution such as KOH.

After the pressure-generating chambers 12 are formed, the piezoelectric layer 70 of the piezoelectric element 300 is polarized by applying a polarization signal of a predetermined voltage to the piezoelectric element 300 for a predetermined time. As a result, the displacement of the piezoelectric element 300 is constant even if voltages are repeatedly applied. The polarization process is performed by applying, for example, a voltage (i.e., polarization voltage) sufficiently higher than the drive voltage, which is supposed to be used, to the piezoelectric element 300. For example, a high voltage, to which a direct electric field of 10 to 30 kv/cm is applied, can be used. In this exemplary embodiment, the drive voltage is set to about 30 V, and the polarization voltage is set to about 70 V. Since the piezoelectric effect is determined to be positive or negative due to the direction positive or negative polarization caused by the polarization process, the direction of the direct electric field, applied to the piezoelectric element 300 in the polarization process, determines such that the piezoelectric effect that enables to function as the drive element of the head can be obtained.

Afterwards, unnecessary portions on the outer circumferences of the passage-forming substrate wafer 110 and the protective substrate wafer 130 are removed by cutting such as dicing or the like. In addition, a nozzle plate 20, in which a nozzle opening 21 is formed, is bonded to the surface of the passage-forming substrate wafer 110, on the opposite side of the protective substrate wafer 130, and a compliance substrate 40 is bonded to the protective substrate wafer 130. Next, the passage-forming substrate wafer 110 is divided into the passage-forming substrate 10 having one-chip size, as shown in FIG. 1. Accordingly, the ink jet recording head of this exemplary embodiment is produced.

As described above, in the method for manufacturing an ink jet recording head in accordance with this exemplary embodiment, the second electrode 80 is formed as a film over the piezoelectric layer 70, the piezoelectric layer 70 and the second electrode 80 are patterned, and then the second heat treatment is performed in the oxygen atmosphere by heating the piezoelectric layer 70 at a predetermined temperature while applying a voltage between the first electrode 60 and the second electrode 80. Then, the complex deficiency is reduced in the piezoelectric layer 70 so that the piezoelectric layer 70 has excellent displacement characteristics (i.e., piezoelectric characteristics). As a result, an ink jet recording head having excellent ink ejecting characteristics (i.e., liquid ejecting characteristics) can be manufactured.

Although the thin-film piezoelectric layer 70 is vulnerable to complex deficiency, the method for manufacturing an ink jet recording head in accordance with this exemplary embodiment can reduce the complex deficiency of the piezoelectric layer and prevent the complex deficiency of the piezoelectric layer from being created again. Accordingly, a liquid ejecting head having excellent displacement characteristics can be produced.

### Second Exemplary Embodiment

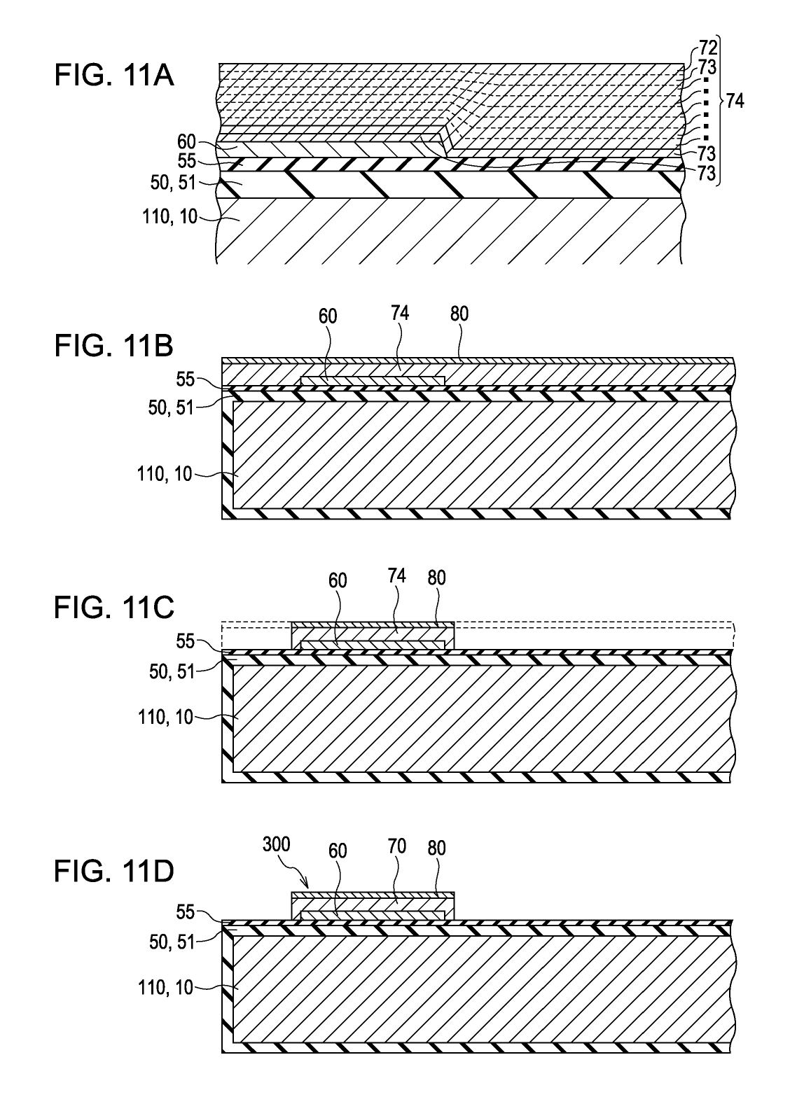

A method for manufacturing an ink jet recording head in accordance with a second exemplary embodiment will be described with reference to FIGS. 11A to 11D. In addition, the ink jet recording head of the second exemplary embodiment is configured the same as the first exemplary embodiment.

In the second exemplary embodiment, methods for sequentially forming an elastic film 50, an insulating film 55, and a first electrode 60 on a passage-forming substrate 10 and a method for forming a plurality of piezoelectric films 73 are the same as those of the first exemplary embodiment, and thus description thereof will be omitted.

As shown in FIG. 11A, an uppermost piezoelectric precursor film 72 is formed by applying a constituent humor for piezoelectric film over the plurality of piezoelectric films 73, followed by heat treatment (application process and drying process). Then, the piezoelectric precursor film 72, dried in the drying process, is degreased by heating it at a predetermined temperature for a predetermined time (degreasing process). The plurality of piezoelectric films 73 and the uppermost piezoelectric precursor film 72 are collectively referred to as a piezoelectric layer precursor 74.

Afterwards, as shown in FIG. 11B, a second electrode 80 made of Ir is formed over the piezoelectric layer precursor 74. Then, as shown in FIG. 11C, portions of the piezoelectric layer precursor 74 and the second electrode 80, opposite to the respective pressure-generating chambers 12, are patterned.

Next, heat treatment is performed at a temperature from 650 to 750° C. while a voltage is being applied between the first electrode 60 and the second electrode 80. This can remove complex deficiency already formed in the crystal of the piezoelectric films 73 while converting the uppermost piezoelectric precursor film 72 into a piezoelectric film 73 by crystallization. That is, the first heat treatment of forming the uppermost piezoelectric layer by crystallizing the uppermost piezoelectric precursor film 72 by heat treatment is performed simultaneously with the second heat treatment. This can form the piezoelectric layer 70 while removing the complex deficiency of the piezoelectric layer 70, except for the uppermost layer, thereby producing a piezoelectric element 300 as shown in FIG. 11D. The complex deficiency-removing mechanism is the same as described in the first exemplary embodiment. In addition, since the uppermost piezoelectric film 73 is crystallized after the patterning of the piezoelectric layer precursor 74 and the second electrode 80, complex deficiency due to the patterning does not occur.

The following processes are the same as those in the first exemplary embodiment, and thus description thereof will be omitted.

As described above, in the method for manufacturing an ink jet recording head in accordance with the second exemplary embodiment, the piezoelectric layer precursor 74 is obtained by forming the uppermost piezoelectric precursor film 72 by applying a solution, which will form the piezoelectric layer 70, over the piezoelectric films 73; the second electrode 80 is formed over the piezoelectric layer precursor 74; and then the piezoelectric layer precursor 74 and the second electrode 80 are patterned and subsequently subjected to the heat treatment at a predetermined temperature while applying a voltage. This can remove the existing complex deficiency from the plurality of piezoelectric films 73 while forming the uppermost piezoelectric film 73. Like the first exemplary embodiment, this method can also reduce the complex deficiency of the piezoelectric layer 70, thereby ensuring excellent displacement characteristics (i.e., piezoelectric characteristics). This also prevents the complex deficiency from occurring again in the piezoelectric layer 70. As a result, an ink jet recording head having excellent ink ejecting characteristics (i.e., liquid ejecting characteristics) can be manufactured.

### Other Exemplary Embodiments

Although the present invention has been described with reference to the exemplary embodiments, it should not be understood that the present invention is limited to the foregoing exemplary embodiments. For example, although the second heat treatment was performed after the piezoelectric layer 70 and the second electrode are patterned in the first exemplary embodiment, it can be performed after the protective substrate wafer 130 is bonded to the passage-forming substrate wafer 110, adjacent to the piezoelectric element 300, or after the pressure-generating chambers 12, the communicating portion 13, the ink supply passages 14, the communicating passages 15, and the like are formed. In these cases, complex deficiency occurring in the piezoelectric layer 70 during the bonding or the forming of the pressure-generating chambers 12 or the like can be removed. When the second heat treatment is performed after the bonding of the protective substrate wafer 130, the heating temperature can preferably be set to a relatively low temperature, for example, 150 to 400° C. in order not to deteriorate other characteristics.

In addition, the second heat treatment can be performed before or after the polarization process of the piezoelectric layer 70. Although the polarization process was performed after the pressure-generating chambers 12 or the like were formed in the first exemplary embodiment, it can be performed directly after the piezoelectric element 300 is formed.

In addition, while the first and second exemplary embodiments have been described as removing the complex deficiency of the piezoelectric layer 70 made of PZT, complex deficiency of a piezoelectric layer made of a differential material can also be removed according to the present invention. In addition, the first and second exemplary embodiments have been described with reference to the complex deficiency created by the interaction between an atom and a hole, this is not limiting complex deficiency that can be removed by the second heat treatment. The complex deficiency created by the interaction between atoms and the complex deficiency created by interaction between holes can be removed by the second heat treatment that heats the piezoelectric layer 70 at a predetermined temperature while applying a voltage between the first electrode 60 and the second electrode 80.

In addition, although the second heat treatment of the first exemplary embodiment was performed in an oxygen atmosphere, the oxygen atmosphere is not essential.

Furthermore, although the Si single-crystal substrate was illustrated as the passage-forming substrate 10 in the foregoing first and second exemplary embodiments, this is not intended to be limiting. For example, the present invention is effective for an SOI substrate, a glass substrate, an MgO substrate, and the like. In addition, although the elastic film 50 made of silicon dioxide was provided in the lowermost layer of the diaphragm, this is not specifically limiting the configuration of the diaphragm.

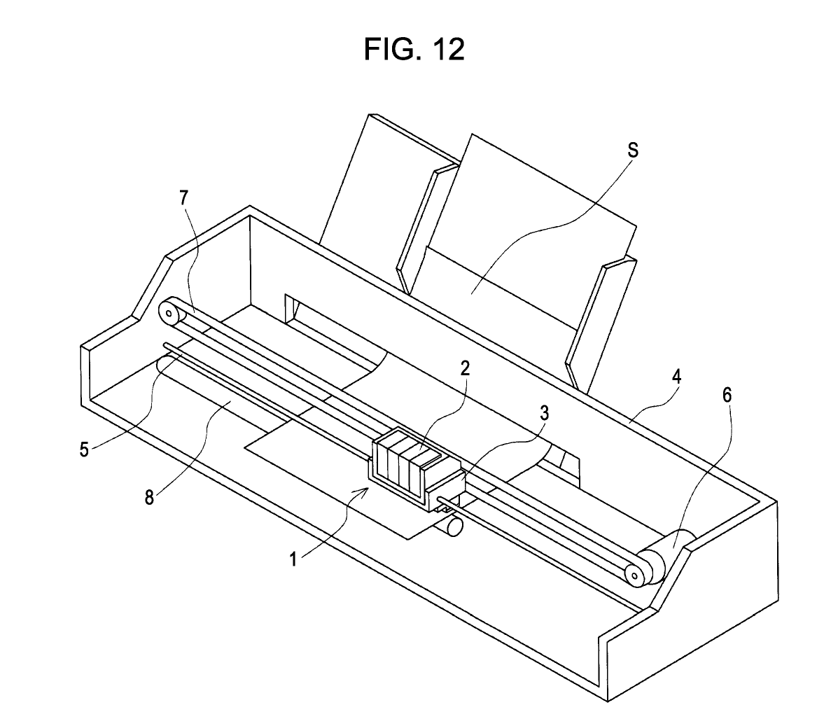

In addition, the ink jet recording head 1 constituting a part of a recording head unit, which includes an ink passage communicating with an ink cartridge, is mounted on an ink jet recording device. FIG. 12 is a perspective view illustrating a schematic configuration of the ink jet recording device.

As shown in FIG. 12, the ink jet recording device, which is the liquid ejecting device of this exemplary embodiment, includes an ink jet recording head 1 (hereinafter, referred to as a recording head) on which an ink cartridge (i.e., liquid-storage unit) 2 is mounted. The ink cartridge 2 has a storage chamber in which a plurality of different colors of ink such as Black (B), Cyan (C), Magenta (M), and Yellow (Y) are stored. The recording head 1 is mounted on a carriage 3, and the carriage 3 on which the recording head 1 is mounted is axially movably provided on a carriage shaft 5 mounted on a device body 4. A drive force of a drive motor 6 is transmitted to the carriage 3 through a plurality of gears (not shown) and a timing belt 7 so that the carriage 3 is moved along the carriage shaft 5. In addition, in the device body 4, a platen 8 is provided along the carriage shaft 5, such that a recording medium S such as a sheet of paper fed by a sheet-feeding device (not shown) is transported on the platen 8.

Although the ink jet recording head 1 mounted on the carriage 3 and moved in the main scanning direction was illustrated as an example of the above-described ink jet recording device, this is not intended to be limiting.

Rather, the present invention is applicable to, for example, a so-called line-type recording device, in which the ink jet recording head 1 is fixed and the recording medium S such as a sheet of paper is moved along the sub-scanning direction to perform a printing operation.

Although the foregoing first and second exemplary embodiments have been described with reference to the ink jet recording head as an example of the liquid ejecting head, the present invention widely covers all types of liquid ejecting heads. Of course, the present invention is applicable to a liquid ejecting head that ejects liquid other than ink. Other types of liquid ejecting heads may include, for example, a variety of recording heads in use for an image recording device such as a printer, a colorant ejecting head used for manufacturing a color filter such as an LCD (Liquid Crystal Display), an electrode material ejecting head used for forming an electrode of, for example, an organic Electro Luminescent (EL) display, an FED (Field Emission Display), a bio-organic material ejecting head used for manufacturing bio chips, and the like.

Furthermore, the present invention is not limited to the method for manufacturing piezoelectric elements mounted on a liquid ejecting head, typically an ink jet recording head, but is applicable to a method for manufacturing piezoelectric elements mounted on different devices.

What is claimed is:

1. A method for manufacturing a liquid ejecting head, which has a piezoelectric element including a first electrode, a piezoelectric layer formed above the first electrode, and a second electrode formed above the piezoelectric layer, the method comprising:
forming the first electrode;
forming a piezoelectric precursor film above the first electrode;
first heat treatment of forming the piezoelectric layer by crystallizing the piezoelectric precursor film by heat treatment;
forming the second electrode above the piezoelectric layer; and
second heat treatment of heating the piezoelectric layer composed of the piezoelectric film at a temperature of 150° C. or more while applying a voltage between the first electrode and the second electrode.

2. The method in accordance with claim 1, wherein the second heat treatment is performed after the second electrode is formed as a film and the piezoelectric layer and the second electrode are patterned.

3. The method in accordance with claim 1, wherein the second heat treatment is performed in an oxygen atmosphere.

4. The method in accordance with claim 1, wherein in the second heat treatment, a voltage of 1 to 30 V is applied between the first electrode and the second electrode.

5. The method in accordance with claim 1, wherein the piezoelectric layer has a thickness not exceeding 5 μm.

6. The method in accordance with claim 1, wherein one or more of the first electrode and the second electrode contain at least one selected from the group consisting of Ni, Cu, Nb, Ru, Rh, Pd, Ag, Sn, Os, Ir, Pt, Au, and Bi.

7. The method in accordance with claim 1, wherein the first heat treatment and the second heat treatment are simultaneously performed after the second electrode is formed on the piezoelectric precursor film.

8. The method in accordance with claim 1, sequentially comprising:
forming a plurality of piezoelectric films by repeating the process of forming a piezoelectric precursor film and the first heat treatment, forming a piezoelectric precursor film in the uppermost layer of the piezoelectric films, and forming the second electrode as a film on the piezoelectric precursor film; and
simultaneously performing the first heat treatment and the second heat treatment, wherein the first heat treatment forms an uppermost piezoelectric film by crystallizing the uppermost piezoelectric precursor film through heat treatment by heating at a temperature of 150° C. or more while applying a voltage between the first electrode and the second electrode.

9. A method for manufacturing an actuator, which has a piezoelectric element including a first electrode, a piezoelectric layer formed on the first electrode, and a second electrode formed on the piezoelectric layer, the method comprising:
forming the first electrode;
forming a piezoelectric precursor film above the first electrode;
first heat treatment of forming a piezoelectric film by crystallizing the piezoelectric precursor;
forming the second electrode; and
second heat treatment of heating the piezoelectric layer composed of the piezoelectric film at a temperature of 150° C. or more while applying a voltage between the first electrode and the second electrode.
